(19) United States
(12) Patent Application Publication
(10) Pub. No.: US 2002/0089021 A1
(43) Pub. Date: Jul. 11, 2002

(54) Semiconductor device with an anti-doped region

(76) Inventor: Joe Ko, Hsinchu (TW)

Correspondence Address: J.C. PATENTS, Suite 250, 4 Venture, Irvine, CA, 92618, US

(21) Appl. No.: 09/912,813

(22) Filed: Jul. 25, 2001

Related U.S. Application Data
(63) Continuation of application No. 09/280,297, filed on Mar. 29, 1999, now abandoned.

(30) Foreign Application Priority Data
Sep. 1, 1998 (TW) 87114449

(51) Int. Cl. H01L 29/76; H01L 29/94; H01L 31/062

(52) U.S. Cl. 257/408; 257/335; 257/336; 257/344

(57) ABSTRACT

A semiconductor device with an anti-type doped region comprises the following structures. A semiconductor substrate is provided. A gate and a gate oxide layer are formed on the semiconductor substrate. A first ion implantation is performed to form a lightly doped region in the semiconductor substrate on both sides of the gate. A second ion implantation is performed to form an anti-type doped region in the lightly doped region near the surface of the semiconductor substrate. The dopant ion type of the anti-type doped region is opposite to the dopant ion type of the lightly doped region. A spacer is formed on the sidewalls of the gate. A third ion implantation is performed, with the spacer serving as a mask, to form a source/drain region. The source/drain region overlaps part of the lightly doped region and the anti-type doped region. The part of the lightly doped region and the anti-type doped region between the gate and the source/drain region are exposed. The implantation dosages of the lightly doped region and the anti-type doped region are about the same.

### CROSS-REFERENCE TO RELATED APPLICATION

This application claims the priority benefit of Taiwan application serial no. 87114449, filed Sep. 01, 1998, the full disclosure of which is incorporated herein by reference.

### BACKGROUND OF THE INVENTION

1. Field of Invention

The present invention generally relates to a semiconductor device, and more particularly to a semiconductor device with an anti-type doped region.

2. Description of Related Art

In accordance with advances in semiconductor fabrication techniques, the integration level of integrated circuits (ICs) increases and the channel lengths of MOS devices become shorter so that the operation speed of MOS devices increases correspondingly. However, certain problems arise, for example short channel effects or hot electron effects, when the channel lengths of MOS devices shrink below a certain level.

If the voltage on the gate of, for example, an NMOS transistor remains the same while the channel length decreases, the horizontal surface electric field of the channel also increases (electric field=voltage/length). The electrons in the channel are thus speeded up by the increased horizontal electric field and the energy of the electrons therefore increases. The energy of the electrons in the channel near the drain is very high. The energy of the electrons is usually higher than the energy of electrons at thermal equilibrium. The electrons with the energy higher than thermal equilibrium are therefore called hot electrons. As the energy of the hot electrons exceeds the semiconductor energy gap, the electrons near the drain original in the valance band then bombard the conduction band. Many electron-hole pairs are thus generated to result in carrier multiplication. Accordingly, the current of the drain increases.

To solve the above problems including short channel effects and hot electron effects, many conventional methods for overcoming the hot electron effect are provided. For example, the lightly doped drain (LDD) structure and the double diffused drain (DDD) structure are commonly used in current semiconductor devices.

FIG. 1 is a schematic, cross-sectional diagram showing a conventional semiconductor device with a lightly doped drain structure. As shown in FIG. 1, a semiconductor substrate 10 is provided. A gate 12 and a gate oxide layer 13 are formed on the semiconductor substrate 10. Spacers 14 are formed on the sidewalls of the gate 12. Source/drain regions 16 are formed on both sides of the gate 12 in the semiconductor substrate 10. Source/drain regions 16 are preferably heavily doped regions. A first lightly doped region 18 and a second lightly doped region 19 are formed between the gate 12 and the source/drain regions 16. The lightly doped drain structure includes the source/drain regions 16, the first lightly doped region 18 and the second lightly doped region 19. The dopant type of the ions in the source/drain regions 16, the first lightly doped region 18 and the second lightly doped region 19 is opposite to the dopant type of the ions in the semiconductor substrate 10.

FIG. 2 is a schematic, cross-sectional diagram showing a conventional semiconductor devices with double diffused drain structure. As shown in FIG. 2, a semiconductor substrate 20 is provided. A gate 22 and a gate oxide layer 23 are formed on the semiconductor substrate 20. Spacers 24 are formed on the sidewalls of the gate 22. Source/drain regions 26 are formed on both sides of the gate 22 in the semiconductor substrate 20. Source/drain regions 26 are preferably heavily doped regions. A lightly doped region 28 is formed around the source/drain regions 26. That is, the lightly doped region 28 includes a region between the gate 22 and the source/drain regions 26, and a region located on the opposite side of the above region. The lightly doped drain structure includes the source/drain regions 26 and the lightly doped region 28. The dopant type of the ions in the source/drain regions 26 and the lightly doped region 28 is opposite to the dopant type of the ions in the semiconductor substrate 20.

The methods of fabricating the lightly doped drain semiconductor device or the double diffused drain semiconductor device include two methods. The two methods are described as follows: (1) double implantation or multiple implantation; and (2) without double implantation. No matter whether method (1) or method (2) is used, there are many disadvantages. The disadvantages of method (1) include an increase of the electric field E_{field} and an increase of the substrate current I_{sub}. The disadvantages of method (2) include a shrinkage of the channel length of the MOS device and a decrease of the drain current I_{off}. The reliability of devices thus decreases.

### SUMMARY OF THE INVENTION

Accordingly, the object of the present invention is to provide a semiconductor device with an anti-type doped region.

Another object of the present invention is to provide a semiconductor device that decreases the surface electric field around the gate of MOS device and that decreases the substrate current. The reliability of devices thus improves.

The invention further provides a lightly doped drain semiconductor device with an anti-type doped region. The semiconductor device comprises a gate formed on a semiconductor substrate. A spacer is formed on the sidewalls of the gate; a source/drain region is formed in the semiconductor substrate on both sides of the gate. A lightly doped region is formed in the semiconductor substrate between the gate and the source/drain region. An anti-type doped region is formed in the lightly doped region between the gate and the source/drain region near the surface of the semiconductor substrate.

To achieve these and other advantages and in accordance with the purpose of the invention, as embodied and broadly described herein, the invention provides a double doped drain semiconductor device with an anti-type doped region. The semiconductor device comprises a gate formed on a semiconductor substrate. A spacer is formed on the sidewalls of the gate. A source/drain region is formed in the semiconductor substrate on both sides of the gate. A lightly doped region is formed in the semiconductor substrate around the source/drain region. An anti-type doped region is formed in the lightly doped region near the surface of the semiconductor substrate.

It is to be understood that both the foregoing general descriptions and the following detailed descriptions are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic, cross-sectional diagram showing a conventional semiconductor device with lightly doped drain structure;

FIG. 2 is a schematic, cross-sectional diagram showing a conventional semiconductor device with a double diffused drain structure;

FIGS. 3A through 3D are schematic, sequential cross-sectional diagrams showing a method of fabricating lightly doped drain semiconductor devices with an anti-type doped region according to the present invention; and

FIGS. 4A through 4D are schematic, sequential cross-sectional diagrams showing a method of fabricating double diffused drain semiconductor devices with an anti-type doped region according to the present invention.

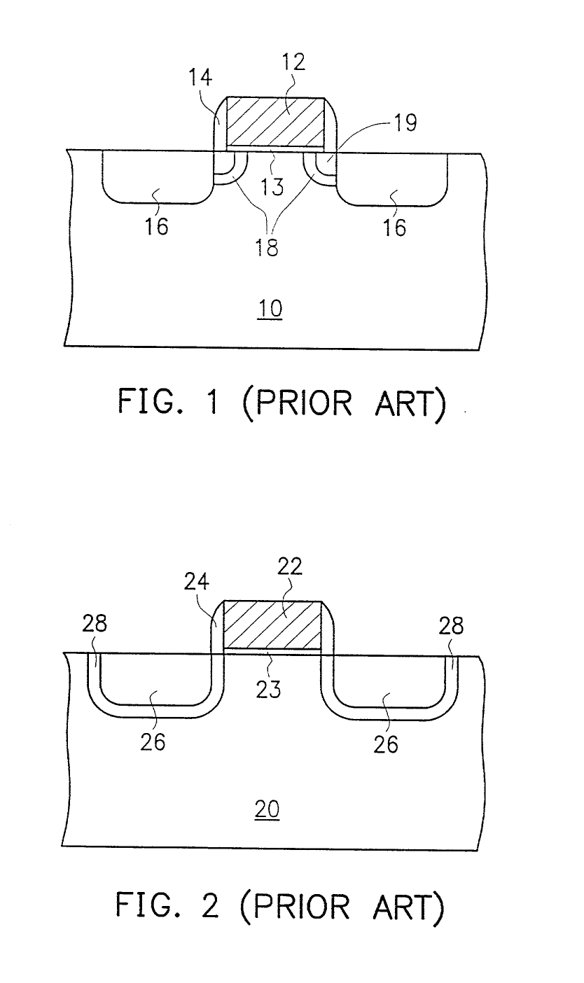

### DESCRIPTION OF THE PREFERRED EMBODIMENTS

The invention provides a semiconductor device with an anti-type doped region. The anti-type doped region can be formed in a lightly doped drain structure semiconductor device or formed in a double doped drain structure semiconductor device. The anti-type doped region is formed on both sides of the gate of the semiconductor device. The dopant ion type of the anti-type doped region is opposite to the dopant ion type of the source/drain region of the semiconductor device. The implantation dosages of the anti-type doped region and the lightly doped region are about the same. The dosage of the anti-type doped region is less than the dosage of the source/drain region. The anti-type doped region is formed to decrease the surface electric field around the gate and decrease the substrate current. The reliability of the semiconductor device thus improves.

First Embodiment

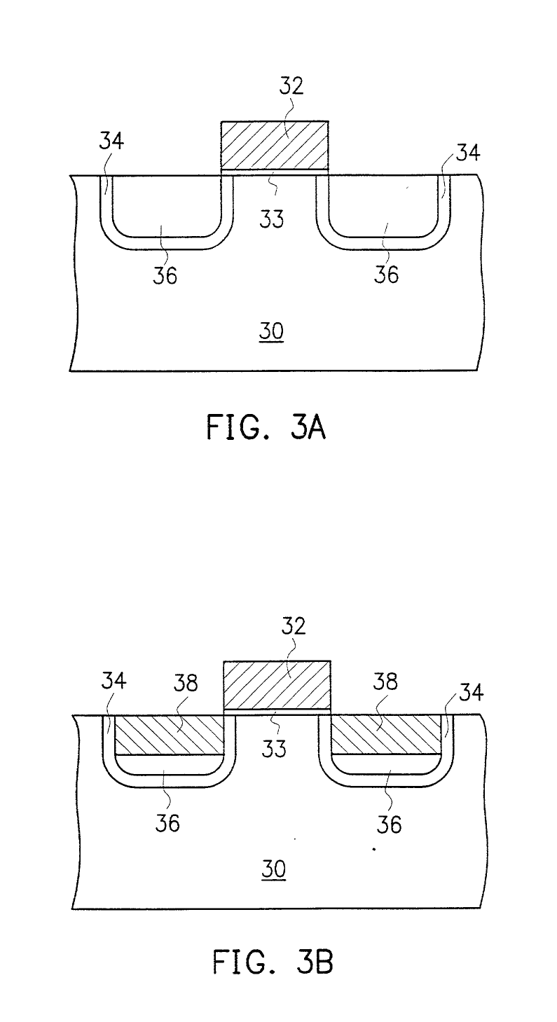

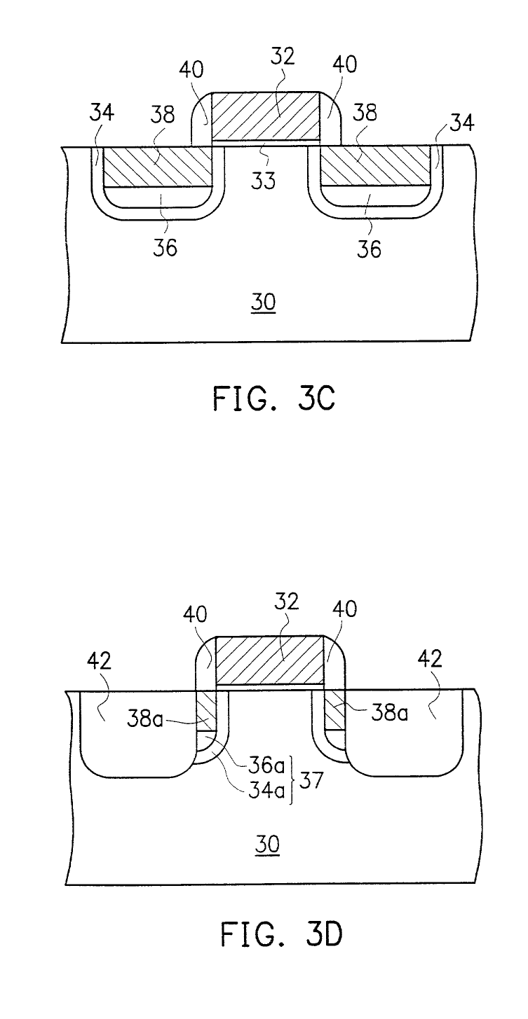

FIGS. 3A through 3D are schematic, sequential cross-sectional diagrams showing a method of fabricating a lightly doped drain semiconductor device with an anti-type doped region according to the invention. As shown in FIG. 3A, a semiconductor substrate 30 is provided. A gate 32 and a gate oxide layer 33 are formed on the semiconductor substrate 30. A first implanting step is performed on the semiconductor substrate 30 to form a first lightly doped region 34 in the semiconductor substrate 30 on both sides of the gate 32. A second implanting step is performed on the semiconductor substrate 30 to form a second lightly doped region 36. The second lightly doped region 36 is formed in the semiconductor substrate 30 and inside the first lightly doped region 34 on both sides of the gate 32. That is, the first lightly doped region 34 is located around the periphery of the second lightly doped region 36 because of the ion diffusion of the first lightly doped region 34. The dopant ion type of the first lightly doped region 34 and the dopant ion type of the second lightly doped region 36 are the same. The dopant ion type of the first lightly doped region 34 (or the dopant ion type of the second lightly doped region 36) is opposite to that of the semiconductor substrate 30. For example, the dopant ion type of the first lightly doped region 34 (or the dopant ion type of the second lightly doped region 36) is N-type and the dopant ion type of the semiconductor substrate 30 is P-type. The dosage of the first lightly doped region is preferably about 10¹³-10¹⁴ atoms/cm².

As shown in FIG. 3B, a third implanting step is performed on the semiconductor substrate 30 to form an anti-type doped region 38 in the second lightly doped region 36 near the surface of the semiconductor substrate 30. The dopant ion types of the anti-type doped region 38 and the semiconductor substrate 30 are the same. For example, the dopant ion types of the anti-type doped region 38 and the semiconductor substrate 30 are both P-type. The dopant ion types of the anti-type doped region 38 is accordingly opposite to the dopant ion types of the dopant ion types of the first lightly doped region 34 (or the dopant ion type of the second lightly doped region 36). In addition, the implantation dosages of the anti-type doped region and the first lightly doped region 34 (or the second lightly doped region 36) are about the same. The dosage of the anti-type doped region is preferably about 10¹³-10¹⁴atoms/cm². The anti-type doped region of the invention is formed to decrease the surface electric field around the gate and decrease the substrate current to improve the semiconductor device's reliability.

As shown in FIG. 3C, a spacer 40 is formed on the sidewalls of the gate 32. The method of fabricating the spacer 40 includes forming an insulating layer on the gate 32 and the semiconductor substrate 30. The material of the insulating layer includes silicon nitride or silicon oxide. An anisotropic etching step is then performed on the insulating layer to form the spacer 40.

As shown in FIG. 3D, a fourth implanting step is performed on the semiconductor substrate 30 to form a heavily doped region 42 with the spacer 40 serving as a mask. The heavily doped region 42 is preferably a source/drain region. The heavily doped region 42 is formed in the semiconductor substrate 30 on both sides of the spacer 40. Then a driving-in step is performed on the heavily doped region 42 and the first lightly doped region 34 (and the second lightly doped region 36) by using a high temperature. The high temperature is preferably about 800-980° C. The dosage of the source/drain region 42 is higher than the dosages of the lightly doped region 34 or 36. The dopant ion type of the source/drain region 42 is opposite to the type of the semiconductor substrate 30. For example, the dopant ion type of the source/drain region 42 is N-type and the dopant ion type of the semiconductor substrate 30 is P-type. The source/drain region 42 overlaps with many parts of the lightly doped region 34 (and 36) and the anti-type doped region 38. The parts of the lightly doped region 34a (and 36a) and the anti-type doped region 38a between the gate 32 and the source/drain region 42 are exposed. The lightly doped region 34a and 36a together form a lightly doped drain structure 37.

Second Embodiment

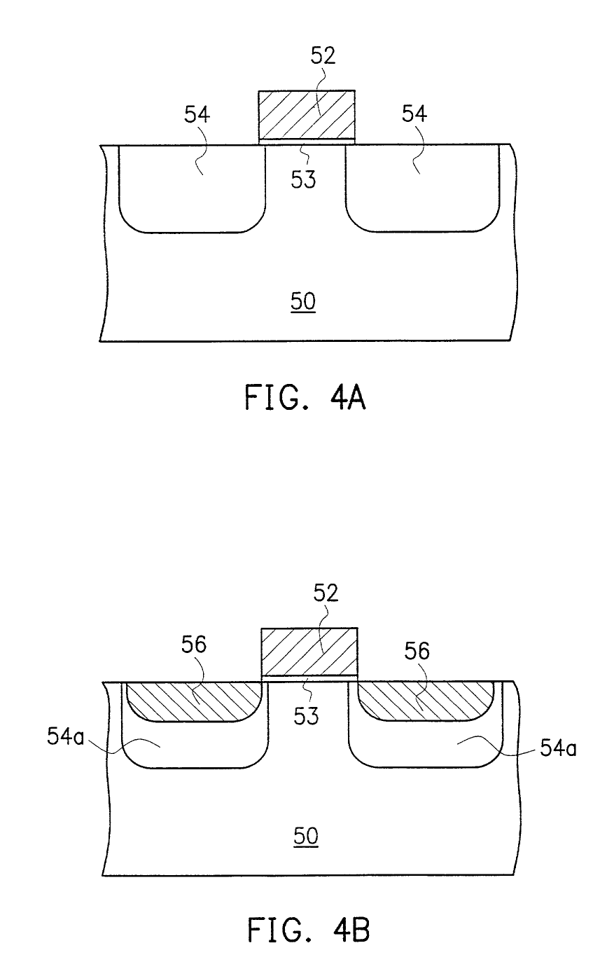

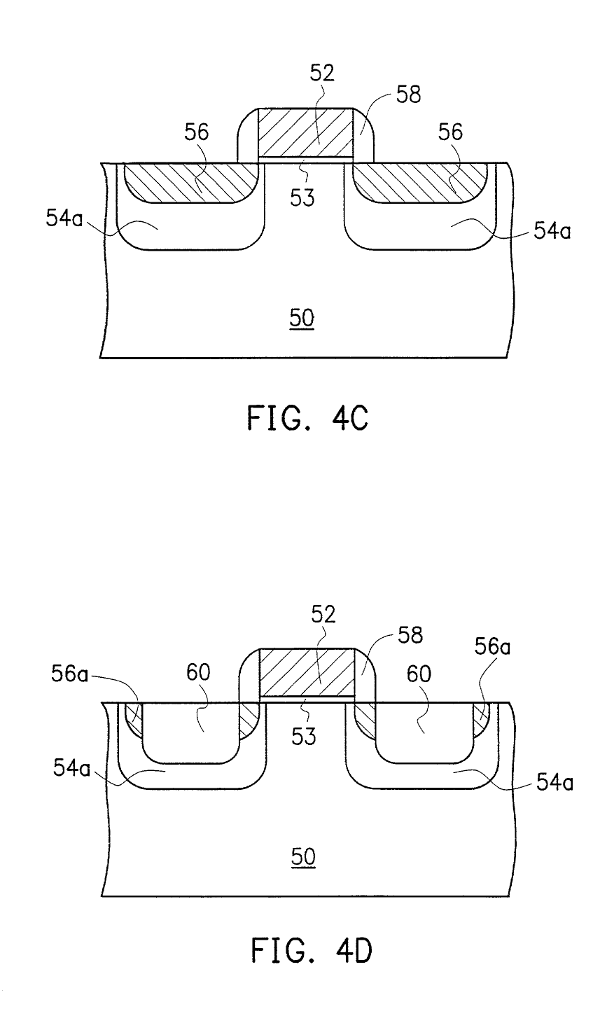

FIGS. 4A through 4D are schematic, sequential cross-sectional diagrams showing a method of fabricating a double diffused drain structure semiconductor device with an anti-type doped region according to the present invention.

As shown in FIG. 4A, a semiconductor substrate 50 is provided. A gate 52 and a gate oxide layer 53 are formed on the semiconductor substrate 50. A first implanting step is performed on the semiconductor substrate 50 to form a lightly doped region 54 in the semiconductor substrate 50 on both sides of the gate 52. The dopant ion type of the lightly doped region 54 is opposite to the type of the semiconductor substrate 50. For example, the dopant ion type of the lightly doped region 54 is N-type and the dopant ion type of the semiconductor substrate 50 is P-type.

As shown in FIG. 4B, a second implanting step is performed on the semiconductor substrate 50 to form an anti-type doped region 56 in the lightly doped region 54 near the surface of the semiconductor substrate 50. The dopant ion types of the anti-type doped region 56 and the semiconductor substrate 50 are the same. For example, the dopant ion types of the anti-type doped region 56 and the semiconductor substrate 50 are both P-type. The dopant ion type of the anti-type doped region 56 is accordingly opposite to the dopant ion type of the lightly doped region 54. In addition, the implantation dosages of the anti-type doped region 56 and the lightly doped region 54 are about the same. The dosage of the anti-type doped region 56 is preferably about 10¹³-10¹⁴ atoms/cm². The anti-type doped region 56 of the invention is formed to decrease the surface electric field around the gate and decrease the substrate current to improve the semiconductor device's reliability.

As shown in FIG. 4C, a spacer 58 is formed on the sidewalls of the gate 52. The method of fabricating the spacer 58 includes forming an insulating layer on the gate 52 and the semiconductor substrate 50. The material of the insulating layer includes silicon nitride or silicon oxide. Then an anisotropic etching step is performed on the insulating layer to form the spacer 58.

As shown in FIG. 4D, a third implanting step is performed on the semiconductor substrate 50 to form a heavily doped region 60 with the spacer 58 serving as a mask. The heavily doped region 60 is preferably a source/drain region. The heavily doped region 60 is formed in the semiconductor substrate 50 on both sides of the spacer 58. Then a driving-in step is performed on the heavily doped region 60 and the lightly doped region 54a by using a high temperature. The high temperature is preferably about 800-980° C. The dosage of the source/drain region 60 is higher than the dosages of the lightly doped region 54. The dopant ion type of the source/drain region 60 is opposite to the type of the semiconductor substrate 50. For example, the dopant ion type of the source/drain region 60 is N-type and the dopant ion type of the semiconductor substrate 50 is P-type. The source/drain region 60 overlaps with many parts of the lightly doped region 54a and the anti-type doped region 56. The parts of the lightly doped region 54a and the anti-type doped region 56a between the gate 52 and the source/drain region 60 are exposed. The anti-type doped region 56a includes a region between the gate 52 and the source/drain regions 60, and a region located on the opposite side of the above region.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor device with an anti-type doped region, wherein the semiconductor device includes a double doped drain structure, comprising:
a semiconductor substrate;
a gate formed on the semiconductor substrate;
a spacer formed on the sidewalls of the gate;
a source/drain region formed in the semiconductor substrate on both sides of the gate;
a lightly doped region formed in the semiconductor substrate and around the source/drain region; and
an anti-type doped region formed in the lightly doped region and near the surface of the semiconductor substrate, wherein the source/drain region is deeper into the substrate than the anti-type doped region.

2. The semiconductor device with the anti-type doped region of claim 1, wherein a dopant ion type of the semiconductor substrate is opposite to a dopant ion type of the source/drain region.

3. The semiconductor device with the anti-type doped region of claim 1, wherein the dopant ion type of the semiconductor substrate is opposite to a dopant ion type of the lightly doped region.

4. The semiconductor device with the anti-type doped region of claim 1, wherein the dopant ion types of the semiconductor substrate and the anti-type doped region are the same.

5. The semiconductor device with the anti-type doped region of claim 1, wherein a dosage of the source/drain region is higher than a dosage of the lightly doped region.

6. The semiconductor device with the anti-type doped region of claim 1, wherein dosages of the lightly doped region and the anti-type doped region are about the same.

7. The semiconductor device with the anti-type doped region of claim 1, wherein the dosage of the anti-type doped region is about 10¹³-10¹⁴ atoms/cm².

8. The semiconductor device with the anti-type doped region of claim 1, further comprising a gate oxide layer formed between the gate and the semiconductor substrate.
